(19) United States
(12) Patent Application Publication
(10) Pub. No.: US 2025/0137844 A1
(43) Pub. Date: May 1, 2025

(54) METROLOGY METHOD OF CALIBRATING AND MONITORING RADIATION IN EUV LITHOGRAPHIC SYSTEMS

(71) Applicant: KLA Corporation, Milpitas, CA (US)

(72) Inventors: Earl Jensen, Santa Clara, CA (US); Joshua Gubler, San Jose, CA (US)

(21) Appl. No.: 18/756,439

(22) Filed: Jun. 27, 2024

Related U.S. Application Data
(60) Provisional application No. 63/546,758, filed on Nov. 1, 2023.

(51) Int. Cl. G01J 1/42; G01J 1/44; G03F 7/00

(52) U.S. Cl. CPC G01J 1/429; G01J 1/44; G03F 7/70033; G03F 7/70041; G03F 7/70508; G03F 7/70516; G03F 7/70558; G01J 2001/446

(57) ABSTRACT

An instrumented substrate may provide a metrology platform for monitoring extreme ultraviolet (EUV) radiation in an image plane of a EUV lithography tool. The instrumented substrate may include in-band dosage sensors. The in-band dosage sensors may generate dosage measurements corresponding to the illumination which is in-band. The instrumented substrate may also include out-of-band dosage sensors and in-band scattered dosage sensors. The instrumented substrate may be housed within a front opening unified pod (FOUP) of a system.

### CROSS-REFERENCE TO RELATED APPLICATIONS

The present application claims the benefit under 35 U.S.C. § 119(e) of U.S. Provisional Application Ser. No. 63/546,758, filed Nov. 1, 2023, titled “A METROLOGY METHOD OF CALIBRATING AND MONITORING RADIATION IN EUV LITHOGRAPHIC SYSTEMS”, which is incorporated herein by reference in the entirety.

### TECHNICAL FIELD

The present disclosure generally relates to monitoring of wafers along a semiconductor process line, and more specifically to measuring extreme ultraviolet light irradiance.

### BACKGROUND

As tolerances on process conditions in semiconductor device processing environments narrows, a demand for improved process monitoring systems increases. Uniformity of illumination radiation, and particularly ultraviolet (UV) and extreme ultraviolet (EUV), within a processing system is one such condition. Therefore, it would be advantageous to provide a device, system, and method that cures the shortcomings described above.

### SUMMARY

An instrumented substrate is described, in accordance with one or more embodiments of the present disclosure. The instrumented substrate may include: a substrate, wherein the substrate is configured to receive illumination, wherein the illumination includes in-band EUV illumination, out-of-band illumination and in-band scattered illumination; a power source; a communication interface; a plurality of conductive traces; one or more in-band dosage sensors, wherein the one or more in-band dosage sensors are configured to generate in-band dosage measurements of the in-band EUV illumination; and a controller including: a memory maintaining program instructions; and one or more processors configured to execute the program instructions.

In some aspects, the instrumented substrate may include one or more out-of-band dosage sensors, wherein the one or more out-of-band dosage sensors are configured to generate out-of-band dosage measurements from the out-of-band illumination.

In some aspects, the controller is configured to compare the in-band dosage measurements with the out-of-band dosage measurements to determine a signal composition of the illumination.

In some aspects, the in-band dosage measurements are divided by the out-of-band dosage measurements to determine the signal composition.

In some aspects, the communication interface is configured to transmit at least one of the in-band dosage measurements, the out-of-band dosage measurements, or the signal composition of the illumination from the instrumented substrate.

In some aspects, the one or more in-band dosage sensors are adjacent to the one or more out-of-band dosage sensors.

In some aspects, the in-band EUV illumination is between 10 and 20 nanometers.

In some aspects, the out-of-band illumination is between 100 and 400 nanometers.

In some aspects, the instrumented substrate may include one or more in-band scattered dosage sensors

In some aspects, the one or more in-band dosage sensors include: an absorptive layer, wherein the absorptive layer defines a cavity and an aperture; a photodiode, wherein the photodiode is disposed in the cavity and aligned with the aperture, wherein the photodiode is configured to receive the illumination through the aperture; an integrator, wherein the integrator is configured to receive voltage from the photodiode and integrate the voltage to determine a dosage; and an analog-to-digital converter, wherein the analog-to-digital converter is configured to convert the dosage to the dosage measurements.

In some aspects, the photodiode includes a silicon photodiode or a silicon carbide photodiode.

In some aspects, the illumination is generated in pulses, wherein the one or more in-band dosage sensors include a comparator, wherein the comparator is configured to receive the voltage from the photodiode, wherein the comparator is configured to detect the pulses of the illumination, wherein the controller is configured to activate and deactivate the integrator based on the pulses detected by the comparator.

In some aspects, the instrumented substrate may include: a plurality of dosage sensors including the comparator, wherein the illumination is scanned across the substrate in a scanning pattern, wherein the controller is configured to determine the scanning pattern from the pulses of the illumination detected by the comparator of the plurality of dosage sensors.

A system is described, in accordance with one or more embodiments of the present disclosure. The system may include: an instrumented substrate including: a substrate, wherein the substrate is configured to receive illumination, wherein the illumination includes in-band EUV illumination and out-of-band illumination; a power source; a communication interface; a plurality of conductive traces; one or more in-band dosage sensors, wherein the one or more in-band dosage sensors are configured to generate in-band dosage measurements from the in-band EUV illumination; and a controller including: a memory maintaining program instructions; and one or more processors configured to execute the program instructions; and an EUV lithography system, wherein the EUV lithography system is configured to generate the illumination.

In some aspects, the instrumented substrate comprising one or more out-of-band dosage sensors, wherein the one or more out-of-band dosage sensors are configured to generate out-of-band dosage measurements from the out-of-band illumination.

In some aspects, the controller is configured to compare the in-band dosage measurements with the out-of-band dosage measurements to determine a signal composition of the illumination.

In some aspects, the communication interface is configured to transmit at least one of the in-band dosage measurements, the out-of-band dosage measurements, or the signal composition of the illumination from the instrumented substrate.

In some aspects, the system includes: a front opening unified pod; wherein the front opening unified pod is configured to receive the signal composition from the communication interface.

In some aspects, the in-band EUV illumination is between 10 and 20 nanometers.

A method is described, in accordance with one or more embodiments of the present disclosure. The method may include: picking and placing an instrumented substrate from a front opening unified pod onto a EUV lithography tool, wherein the instrumented substrate includes: a substrate, wherein the substrate is configured to receive illumination, wherein the illumination includes in-band EUV illumination and out-of-band illumination; a power source; a communication interface; a plurality of conductive traces; one or more in-band bolometers, wherein the one or more in-band dosage sensors are configured to generate in-band dosage measurements from the in-band EUV illumination; and a controller including: a memory maintaining program instructions; and one or more processors configured to execute the program instructions; generating the illumination by the EUV lithography tool; generating the in-band dosage measurements and the out-of-band dosage measurements from the illumination; and returning the instrumented substrate to the front opening unified pod.

### BRIEF DESCRIPTION OF THE DRAWINGS

The numerous advantages of the disclosure may be better understood by those skilled in the art by reference to the accompanying figures in which:

FIG. 1A illustrates a top view of an instrumented substrate, in accordance with one or more embodiments of the present disclosure.

FIG. 1B illustrates a perspective view of the instrumented substrate receiving illumination, in accordance with one or more embodiments of the present disclosure.

FIG. 2A illustrates a cross-section view of a dosage sensor of the instrumented substrate, in accordance with one or more embodiments of the present disclosure.

FIG. 2B illustrates a simplified block diagram of the dosage sensor connected to a controller of the instrumented substrate, in accordance with one or more embodiments of the present disclosure.

FIG. 2C illustrates a graph in which the dosage sensor of the instrumented substrate activates an integrator, in accordance with one or more embodiments of the present disclosure.

FIG. 3 illustrates a simplified block diagram of a system including the instrumented substrate, in accordance with one or more embodiments of the present disclosure.

FIG. 4 illustrates a flow diagram of a method, in accordance with one or more embodiments of the present disclosure.

### DETAILED DESCRIPTION

The present disclosure has been particularly shown and described with respect to certain embodiments and specific features thereof. The embodiments set forth herein are taken to be illustrative rather than limiting. It should be readily apparent to those of ordinary skill in the art that various changes and modifications in form and detail may be made without departing from the spirit and scope of the disclosure. Reference will now be made in detail to the subject matter disclosed, which is illustrated in the accompanying drawings.

Embodiments of the present disclosure are directed to an instrumented substrate. The instrumented substrate may provide a metrology platform for monitoring extreme ultraviolet (EUV) radiation in an image plane of a EUV lithography tool. The instrumented substrate may include in-band dosage sensors. The in-band dosage sensors may generate in-band dosage measurements corresponding to the illumination which is in-band. The instrumented substrate may also include out-of-band dosage sensors and in-band scattered dosage sensors. The instrumented substrate may be housed within a front opening unified pod (FOUP) of a system.

U.S. Pat. No. 11,668,601, titled “Instrumented substrate apparatus”; U.S. Pat. No. 11,823,925, titled “Encapsulated instrumented substrate apparatus for acquiring measurement parameters in high temperature process applications”; U.S. Pat. No. 7,855,549, titled “Integrated process condition sensing wafer and data analysis system”; U.S. Pat. No. 9,356,822, titled “Automated interface apparatus and method for use in semiconductor wafer handling systems”; U.S. Pat. No. 10,215,626, titled “Method and system for measuring radiation and temperature exposure of wafers along a fabrication process line”; U.S. Pat. No. 9,964,440, titled “Wafer level spectrometer”; U.S. Patent Publication Number 2022/0189803, titled “Sensor configuration for process condition measuring devices”; U.S. Patent Publication Number 2020/0103746, titled “Apparatus and method for monitoring reflectivity of the collector for extreme ultraviolet radiation source”; U.S. Pat. No. 10,146,133, titled “Lithographic apparatus and method”; U.S. Patent Publication Number 2023/0035511, titled “Lithographic apparatus and method for drift compensation”; U.S. Pat. No. 11,569,138, titled “System and method for monitoring parameters of a semiconductor factory automation system”; are each incorporated herein by reference in the entirety.

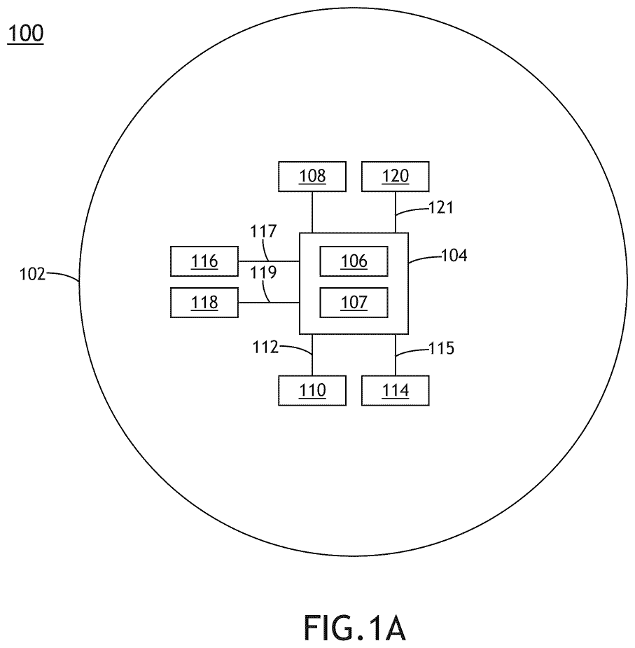

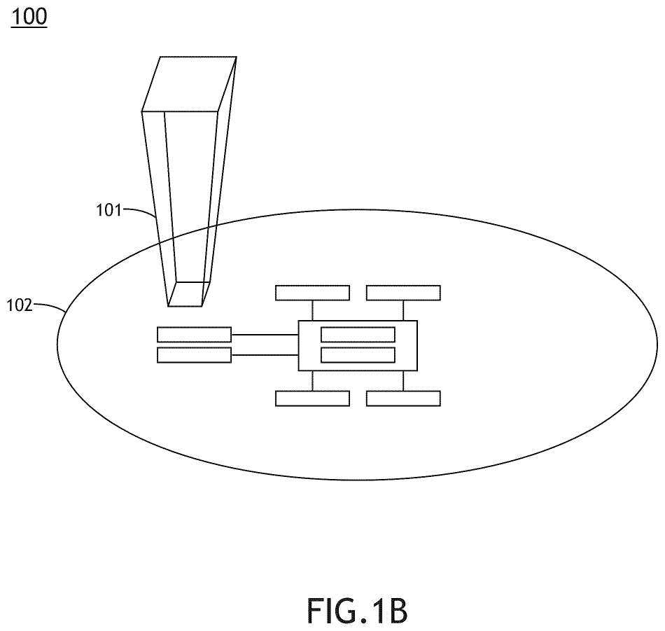

FIGS. 1A-1B illustrates an instrumented substrate 100, in accordance with one or more embodiments of the present disclosure. The instrumented substrate 100 may be an instrumented substrate assembly, substrate device, instrumented wafer, instrumented wafer substrate, sensor wafer, substrate monitoring device, instrumented substrate device, inspection substrate, inspection wafer, measurement wafer, registration measuring substrate, registration wafer, and the like.

The instrumented substrate 100 may include one or more of a substrate 102, controller 104, processors 106, memory 107, power source 108, communication interface 110, conductive traces 112, sensors 114, in-band dosage sensors 116, out-of-band dosage sensors 118, and/or in-band scattered dosage sensors 120.

The substrate 102 may include any substrate material. For example, the substrate 102 may include a wafer. For example, the substrate 102 may include a wafer structure formed from quartz, glass (e.g., fused silica glass wafer, borosilicate glass wafer, and the like), silicon (e.g., single crystal silicon), silicon carbide, silicon nitride, doped (e.g., n-type or p-type) silicon, carbon fiber stabilized epoxy matrices, one or more ceramic materials, glass carbon fibers, one or more composite materials, or a combination thereof. For example, the substrate 102 may be formed from a composite material including two or more layers of material that may be bonded together or two or more materials that may be intermixed in a single layer or multiple layers. The substrate 102 may also be a composite material such as graphite/epoxy or a laminate formed from silicon, graphite/epoxy, silicon. The substrate 102 may be made of the same or similar materials to a production substrate.

The substrate 102 may take on the same, or similar, size and shape as a standard substrate processed by a semiconductor device processing system. The substrate 102 may have physical parameters that approximate the physical parameters of a production substrate used in the manufacture of integrated circuits or other electronics. The substrate 102 may have dimensions conforming to that of a Semiconductor Equipment and Materials International (SEMI®) wafer. The substrate 102 may include a round substrate (e.g., a round wafer) having a selected diameter. For example, the substrate 102 may have a diameter between 25 and 450 mm, such as, but not limited to, 25 mm, 50 mm, 75 mm, 100 mm, 125 mm, 150 mm, 200 mm, 300 mm, or 450 mm. For instance, the substrate 102 may include a diameter between 100 and 300 mm. Additionally, the substrate 102 may have a thickness between 275 and 925 μm. The thickness may be based on the diameter. The substrate 102 may also have a thickness that approximates the corresponding thickness of the production substrate, although the thickness may be slightly larger than the production substrate to accommodate additional electronics and/or other components of the instrumented substrate 100. The substrate 102 may also be a glass like rectangular reticle.

The substrate 102 may include a top surface and/or a bottom surface. In embodiments, the top surface and/or the bottom surface of the substrate 102 may be planar. The bottom surface may also be referred to as a backside. One or more components of the instrumented substrate 100 may be disposed on the top surface and/or the bottom surface of the substrate 102. For example, the controller 104, processors 106, memory 107, power source 108, communication interface 110, conductive traces 112, sensors 114, in-band dosage sensors 116, out-of-band dosage sensors 118, and/or in-band scattered dosage sensors 120 may be disposed on the substrate 102. Any of the various components of the instrumented substrate 100 may be disposed on and/or embedded in the substrate 102. The components of the instrumented substrate 100 may be disposed on the top surface. The substrate 102 may define one or more cavities. The substrate 102 may define one or more cavities in the top surface. The cavities may be defined by etching, precision grinding, or the like. Any of the various components of the instrumented substrate 100 may be embedded in the cavities, and thereby be embedded in the substrate 102.

The controller 104, processors 106, memory 107, power source 108, communication interface 110, conductive traces 112, sensors 114, in-band dosage sensors 116, out-of-band dosage sensors 118, and/or in-band scattered dosage sensors 120 may be disposed at one or more locations on the substrate 102. It is noted that the arrangement and number of the controller 104, processors 106, memory 107, power source 108, communication interface 110, conductive traces 112, sensors 114, in-band dosage sensors 116, out-of-band dosage sensors 118, and/or in-band scattered dosage sensors 120 depicted are not limiting and are provided merely for illustrated purposes. The controller 104, processors 106, memory 107, power source 108, communication interface 110, conductive traces 112, sensors 114, in-band dosage sensors 116, out-of-band dosage sensors 118, and/or in-band scattered dosage sensors 120 may be configured in several patterns, shapes, and quantities. One consideration in the location of the controller 104, processors 106, memory 107, power source 108, communication interface 110, conductive traces 112, sensors 114, in-band dosage sensors 116, out-of-band dosage sensors 118, and/or in-band scattered dosage sensors 120 on the substrate 102 may be to maintain a center of gravity of the instrumented substrate 100 at a center of the substrate 102.

The controller 104, processors 106, memory 107, power source 108, communication interface 110, conductive traces 112, sensors 114, in-band dosage sensors 116, out-of-band dosage sensors 118, and/or in-band scattered dosage sensors 120 may be formed on the substrate 102 via microelectromechanical system (MEMS) fabrication, such as, but not limited to, wet etching, dry etching, or electrical discharge machining.

The controller 104, processors 106, memory 107, power source 108, communication interface 110, sensors 114, in-band dosage sensors 116, out-of-band dosage sensors 118, and/or in-band scattered dosage sensors 120 may be coupled by the conductive traces 112. The conductive traces 112 may include any conductive material, such as, but not limited to, aluminum.

The controller 104 may provide data collection and data storage functionality to the instrumented substrate 100. The controller 104 may be configured to send and/or receive data including, but not limited to, data from the communication interface 110, sensors 114, the in-band dosage sensors 116, the out-of-band dosage sensors 118, and/or the in-band scattered dosage sensors 120.

The controller 104 may include processors 106 and memory 107. The memory 107 may store the processing conditions and program instructions for the operation of the instrumented substrate 100. The processors 106 may be configured to execute the program instructions maintained on the memory 107, the program instructions causing the processors 106 to execute any of the various process steps described.

The power source 108 may be a power supply. The power source 108 may include one or more batteries (e.g., rechargeable batteries), a wired power source, or the like. The power source 108 may provide power to any of the various components of the instrumented substrate 100. The power source 108 may optionally include one or more solar cells. The power source 108 may be embedded into the substrate 102. The power source 108 may provide power storage functionality to the instrumented substrate 100.

The communication interface 110 may include any wireline communication protocol (e.g., DSL-based interconnection, cable-based interconnection, T9-based interconnection, USB, and the like) or wireless communication protocol (e.g., GSM, GPRS, CDMA, EV-DO, EDGE, WiMAX, 3G, 4G, 4G LTE, 5G, Wi-Fi protocols, RF, Bluetooth, Intermediate System to Intermediate System (IS-IS), and the like). By way of another example, the communication interface 110 may include communication protocols including, but not limited to, radio frequency identification (RFID) protocols, open-sourced radio frequencies, and the like. By way of another example, the communication interface 110 may include inductive wireless communications and/or inductive wireless charging. For instance, the communication interface 110 may use On-Off keying and backscatter modulation for bidirectional data transfer together with inductive power transfer for battery charging. Accordingly, an interaction between the various devices may be determined based on one or more characteristics including, but not limited to, cellular signatures, IP addresses, MAC addresses, Bluetooth signatures, radio frequency identification (RFID) tags, and the like. The wireless communication may include wireless nearfield communication.

The sensors 114 may generate sensor measurements 115. The sensor measurements 115 may be generated by detecting one or more processing conditions. The processing conditions may refer to various processing parameters used in manufacturing an integrated circuit. Processing conditions may include any parameter used to control semiconductor manufacture or any condition a manufacturer would desire to monitor such as, but not limited to, temperature, etch rate, thickness of a layer on a substrate, processing chamber pressure, gas flow rate within the chamber, gaseous chemical composition within the chamber, position within a chamber, ion current density, ion current energy, light energy density, and vibration and acceleration of a wafer or other substrate within a chamber or during movement to or from a chamber.

The sensors 114 may include any discrete measurement device including, but not limited to, temperature sensors, pressure sensors, radiation sensors, chemical sensors, multi-axis accelerometers, multi-axis angular rate sensor, light sensors, barometric pressure sensors, capacitive sensors, time sensors, position sensors, line sensors, or a combination thereof. For example, the sensors 114 may include one or more temperature sensors configured to acquire one or more parameters indicative of temperature. For instance, the one or more temperature sensors may include, but are not limited to, one or more thermocouple (TC) devices (e.g., thermoelectric junction), one or more resistance temperature devices (RTDs) (e.g., thin film RTD), or the like. By way of another example, in the case of pressure measurements, the sensors 114 may include, but are not limited to, a piezoelectric sensor, a capacitive sensor, an optical sensor, a potentiometric sensor or the like. By way of another example, in the case of radiation measurements, the sensors 114 may include, but are not limited to, one or more light detectors (e.g., photovoltaic cell, photoresistor, and the like) or other radiation detectors (e.g., solid state detector). By way of another example, in the case of chemical measurements, the sensors 114 may include, but are not limited to, one or more chemiresistors, gas sensors, pH sensors, or the like. By way of another example, in the case of acceleration measurements, the multi-axis accelerometer may be an acceleration measuring type measuring 3-axis or 6-axis. By way of another example, in the case of rotation rates measurements, the multi-axis angular rate sensor may be a gyroscope. The multi-axis angular rate sensor may measure 3-axis rotation rates. By way of another example, in the case of light measurements, the light sensor may be a light measuring type with an excitation source. By way of another example, in the case of pressure measurements, the barometric pressure sensor may generate local barometric pressure of the instrumented substrate 100. By way of another example, in the case of capacitive measurements, the capacitive sensor may direct sample a proximity of the instrumented substrate 100 relative to another component. By way of another example, in the case of time measurements, the time sensor may generate one or more time delay parameters.

The instrumented substrate 100 may be configured to receive illumination 101. The illumination 101 may include may include one or more selected wavelengths of light including, but not limited to, extreme ultraviolet (EUV) illumination. The EUV illumination may include a wavelength between 10 and 121 nanometers. The illumination 101 may include any range of in-band wavelengths. The EUV illumination may include in-band EUV illumination between 10 and 20 nanometers. For example, the EUV illumination may include in-band EUV illumination at 13.5 nanometers. The in-band EUV illumination may include an irradiance of approximately 500 mW/cm\hat{ }2. The in-band EUV illumination may include an energy in a range of 1 eV to 100 eV.

The illumination 101 may also include out-of-band illumination. The out-of-band illumination may be out-of-band ultraviolet (UV) illumination. The out-of-band UV illumination may be outside of the 10 to 20 nanometers band. The out-of-band UV illumination may be between 20 and 400 nanometers. The out-of-band UV illumination may be between 100 and 400 nanometers. For example, the out-of-band UV light may be between 200 and 400 nanometers. The out-of-band UV light may include irradiance levels which are unknown a-priori.

The instrumented substrate 100 may be exposed to the illumination 101 with a selected area. For example, the substrate 102 may be exposed to the illumination 101 with a 33 mm by 16 mm rectangle, a 16 mm by 16 mm square, or a value therebetween. The area exposed by the illumination 101 may also be referred to as a scan area.

The in-band dosage sensors 116 and/or the out-of-band dosage sensors 118 may each be exposed to the illumination 101 in the scan area. The in-band dosage sensors 116 may be adjacent to the out-of-band dosage sensors 118, such that the in-band dosage sensors 116 and the out-of-band dosage sensors 118 are within the scan area at the same time. For example, the in-band dosage sensors 116 and the out-of-band dosage sensors 118 may be disposed one millimeter apart, or less.

The illumination 101 may also include in-band scattered EUV illumination. The in-band scattered EUV illumination may be in-band with the in-band EUV illumination. For example, the in-band scattered EUV illumination may include EUV illumination between 10 and 20 nanometers (e.g., 13.5 nanometers). The in-band scattered EUV illumination may also be referred to as flare. The in-band scattered EUV illumination may be a portion of the in-band EUV illumination which is scattered outside of the scan area exposed by the illumination 101. The in-band scattered EUV illumination may be the diffuse in-band radiation that occurs in the fields adjacent to the exposure field.

The in-band scattered dosage sensors 120 may be disposed away from the in-band dosage sensors 116 and the out-of-band dosage sensors 118, such that the in-band scattered dosage sensors 120 are outside of the scan area while the in-band dosage sensors 116 and the out-of-band dosage sensors 118 are disposed within the scan area. For example, the in-band scattered dosage sensors 120 may be disposed tens or hundreds of millimeters apart from the in-band dosage sensors 116 and the out-of-band dosage sensors 118.

The illumination 101 may be generated in pulses. The pulses may include a selected frequency. For example, the pulses may include a frequency of 50 KHz.

The illumination 101 may not be parked on any given spot of the instrumented substrate 100. Instead, the illumination 101 may be scanned across the instrumented substrate 100 in a scanning pattern. The scanning pattern may include, but is not limited to, a serpentine scanning pattern. The illumination 101 may include a curtain of modulated photons which may be scanned across the instrumented substrate 100. The illumination 101 may be scanned across the instrumented substrate 100 in the pulses over the various components of the instrumented substrate 100, such as, but not limited to, the substrate 102, controller 104, processors 106, memory 107, power source 108, communication interface 110, conductive traces 112, sensors 114, in-band dosage sensors 116, out-of-band dosage sensors 118, and/or in-band scattered dosage sensors 120. The irradiance of the illumination 101 may deposit a dosage of energy on the substrate 102, controller 104, processors 106, memory 107, power source 108, communication interface 110, conductive traces 112, sensors 114, in-band dosage sensors 116, out-of-band dosage sensors 118, and/or in-band scattered dosage sensors 120.

The illumination 101 may include a field with a uniformity. The controller 104 may determine the field uniformity of the illumination 101 using the in-band dosage sensors 116, the out-of-band dosage sensors 118, and/or the in-band scattered dosage sensors 120.

The in-band dosage sensors 116, out-of-band dosage sensors 118, and/or in-band scattered dosage sensors 120 may absorb energy from the illumination 101. For example, the in-band dosage sensors 116 and/or in-band scattered dosage sensors 120 may absorb energy from the illumination at wavelengths between 10 and 20 nanometers (e.g., 13.5 nanometers). The in-band dosage sensors 116 and/or in-band scattered dosage sensors 120 may be sensitive to EUV radiation of wavelengths between 10 and 20 nanometers. By way of another example, the out-of-band dosage sensors 118 may absorb energy from the illumination at wavelengths between 100 and 400 nanometers. The out-of-band dosage sensors 118 may be sensitive to EUV radiation of wavelengths out-of-band. The out-of-band dosage sensors 118 may measure the illumination 101 on other selected bands.

The in-band dosage sensors 116 and the out-of-band dosage sensors 118 may generate in-band dosage measurements 117 and out-of-band dosage measurements 119, respectively, from the illumination 101 in the scan area. The in-band dosage measurements 117 and the out-of-band dosage measurements 119 may correspond to the amount of the illumination 101 which is in-band and out-of-band, respectively, in the scan area. The in-band dosage sensors 116 and/or the out-of-band dosage sensors 118 may detect the power of the illumination 101 with a relatively-wide spectral acceptance.

The controller 104 may compare the in-band dosage measurements 117 with the out-of-band dosage measurements 119 to determine a signal composition of the illumination 101. For example, the signal composition may include luminous power at the wavelengths of the illumination 101. A majority of the signal may be in-band. However, a portion of the signal may be out-of-band. The signal composition may indicate the luminous power of the wavelengths which are in-band and may also indicate the luminous power of the wavelengths which are out-of-band. The signal composition may be determined in terms of a fractional signal composition, where the luminous power of the wavelengths which are in-band are determined as a fraction of the total luminous power and/or as a fraction of the luminous power of the wavelengths which are out-of-band. For example, the in-band dosage measurements 117 may be divided by the out-of-band dosage measurements 119 to determine the signal composition of the illumination 101.

The controller 104 may determine the signal composition of the illumination 101 as the in-band dosage measurements 117 and/or the out-of-band dosage measurements 119 are received. Thus, the signal composition of the illumination 101 may be determined in real time or in near-real time. Determining the signal composition of the illumination 101 as the in-band dosage measurements 117 and/or the out-of-band dosage measurements 119 are received may be beneficial to reduce the requirements of the memory 107. For example, the signal composition of the illumination 101 may be stored in memory 107 without storing the in-band dosage measurements 117 and/or the out-of-band dosage measurements 119 in memory.

The in-band scattered dosage sensors 120 may be configured to generate in-band scattered dosage measurements 121 from the illumination 101 outside of the scan area. The in-band scattered dosage measurements 121 may correspond to the amount of the illumination 101 which is in-band and absorbed by the in-band scattered dosage sensors 120 outside of the scan area while the in-band dosage sensors 116 and the out-of-band dosage sensors 118 are in the scan area of the illumination 101.

The in-band dosage sensors 116, the out-of-band dosage sensors 118, and/or the in-band scattered dosage sensors 120 may include any light sensor. For example, the in-band dosage sensors 116, the out-of-band dosage sensors 118, and/or the in-band scattered dosage sensors 120 may include, but are not limited to, a light sensor capable of sensing the illumination 101. The in-band dosage sensors 116, the out-of-band dosage sensors 118, and/or the in-band scattered dosage sensors 120 may include, but are not limited to, one or more light detectors (e.g., photovoltaic cell, photoresistor and the like) or other radiation detectors (e.g., solid state detector).

The in-band dosage measurements 117, the out-of-band dosage measurements 119, the signal composition determined from the in-band dosage measurements 117 and the out-of-band dosage measurements 119, and/or the in-band scattered dosage measurements 121 may be stored in the memory 107.

The controller 104 may be configured to send the in-band dosage measurements 117, the out-of-band dosage measurements 119, the signal composition determined from the in-band dosage measurements 117 and the out-of-band dosage measurements 119, and/or the in-band scattered dosage measurements 121 from the instrumented substrate 100 through the communication interface 110.

The controller 104 may determine the field uniformity of the illumination 101. The controller 104 may determine the field uniformity of the illumination 101 with a few of the in-band dosage sensors 116, the out-of-band dosage sensors 118, and/or the in-band scattered dosage sensors 120. The in-band dosage sensors 116, the out-of-band dosage sensors 118, and/or the in-band scattered dosage sensors 120 may include a selected spatial resolution for determining the field uniformity. With even a few of the in-band dosage sensors 116, the out-of-band dosage sensors 118, and/or the in-band scattered dosage sensors 120, the substrate 102 can be scanned under the field to determine the field uniformity. The field of the illumination 101 may be very uniform with no or little adjustment to compensate. Hence, there may be no need for spatial resolution of the in-band dosage sensors 116, the out-of-band dosage sensors 118, and/or the in-band scattered dosage sensors 120 for determining the field in a single measurement.

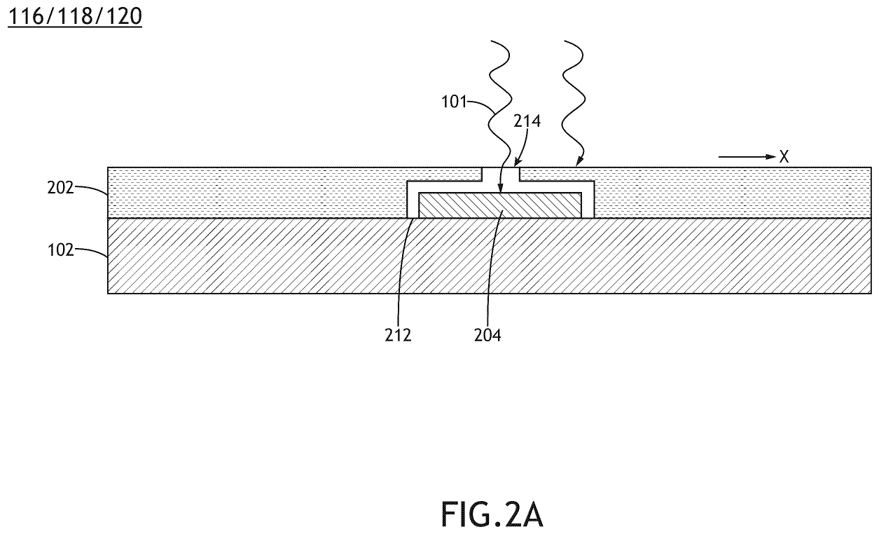

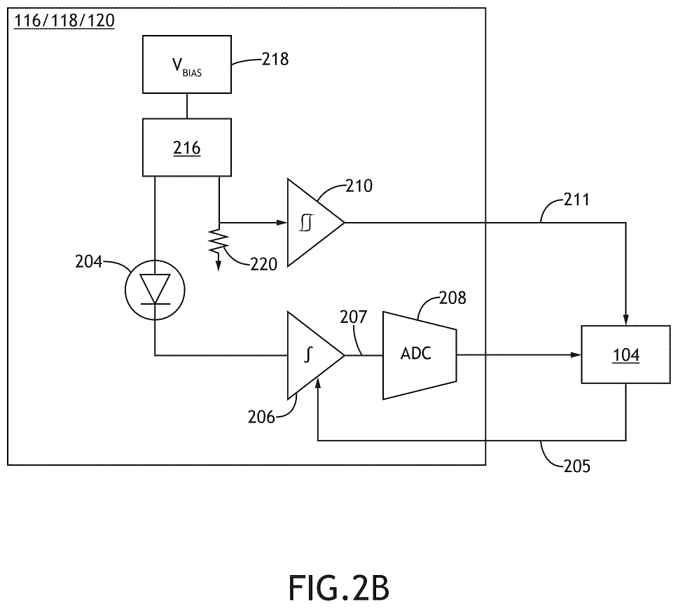

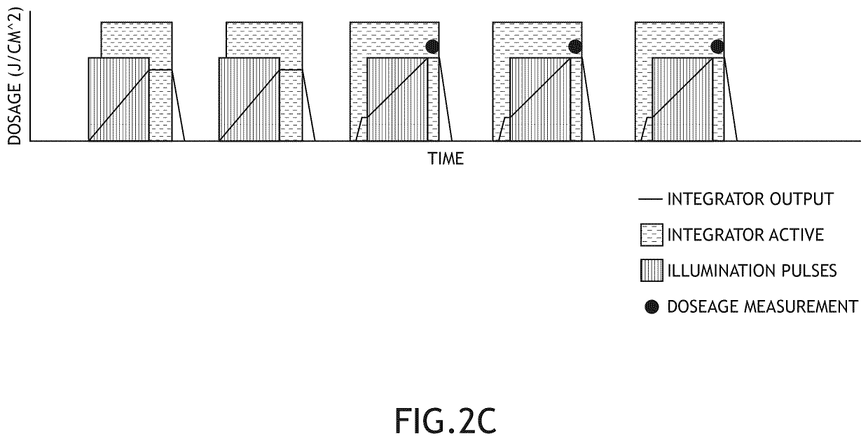

FIGS. 2A-2C illustrate the in-band dosage sensors 116, out-of-band dosage sensors 118, and/or in-band scattered dosage sensors 120, in accordance with one or more embodiments of the present disclosure. The in-band dosage sensors 116, out-of-band dosage sensors 118, and/or in-band scattered dosage sensors 120 may include an absorptive layer 202, a photodiode 204, an integrator 206, an analog-to-digital converter 208, a comparator 210, a current mirror 216, a bias voltage source 218, and/or a resistor 220. The in-band dosage sensors 116, out-of-band dosage sensors 118, and/or in-band scattered dosage sensors 120 may be slit integrated energy (SLIE) sensors.

The absorptive layer 202 may be disposed on the substrate 102. The absorptive layer 202 and the substrate 102 may include a selected thickness. For example, the absorptive layer 202 and the substrate 102 may include a thickness of 1.2 mm.

The absorptive layer 202 may be an absorber. The absorptive layer 202 may include, but is not limited to, a material that is absorptive of the illumination 101. The absorptive layer 202 may be made of a selected material, such as silicon or silicon dioxide. The absorptive layer 202 may absorb the illumination 101, including the in-band EUV illumination and/or the out-of-band illumination. The absorptive layer 202 may include, but are not limited to, an absorber capable of absorbing the in-band EUV illumination and/or the out-of-band illumination. For example, the absorptive layer 202 may be an absorber for the 13.5 nanometers EUV illumination.

The absorptive layer 202 may define a cavity 212. The photodiode 204 may be disposed in the cavity 212.

The absorptive layer 202 may seal the photodiode 204 to the substrate 102. For example, the absorptive layer may hermetically seal the photodiode 204. The hermetic seal may protect against environmental elements, such as temperature and moisture. The absorptive layer 202 may be disposed over and/or around the photodiode 204.

The photodiode 204 may include a silicon photodiode, a silicon carbide photodiode, or the like. The photodiode 204 may be very shallow junction photodiode.

The absorptive layer 202 may define an aperture 214. The aperture 214 may be defined from a top surface of the absorptive layer 202 through to the cavity 212. The cavity 212 may be disposed below the aperture 214. The photodiode 204 may be aligned with the aperture 214. The photodiode 204 may be configured to receive the illumination 101. For example, the photodiode 204 may receive the illumination 101 through the aperture 214. The aperture 214 may be an aperture by which the illumination 101 passes through the absorptive layer 202 to the photodiode 204. The absorptive layer 202 may define the aperture 214 by embedding a disk (not depicted) with a through hole in the absorptive layer.

The photodiode 204 may be configured to generate a current. The photodiode 204 may be generate the current in response to receiving the illumination 101. The photodiode 204 may be sensitive to the illumination 101. For example, the photodiode 204 of the in-band dosage sensors 116 and/or the in-band scattered dosage sensors 120 may be sensitive to the in-band illumination. The photodiode 204 may detect the illumination 101 down to 1 nanometer. The photodiode 204 may include a responsivity, R, of 0.25 A/W for the illumination 101 at 13.5 nanometers. By way of another example, the photodiode 204 of the out-of-band dosage sensors 118 may be sensitive to the out-of-band illumination.

The integrator 206 may include an operational amplifier and a capacitor as an electronic integration circuit. The integrator 206 may include an operational amplifier (op amp) integrator circuit (not depicted). The integrator 206 may define a gain via the capacitor. The gain for the out-of-band dosage sensors 118 and/or the in-band scattered dosage sensors 120 may be much higher than the gain for the in-band dosage sensors 116. The gain may be much higher to compensate for the lower power received of the out-of-band illumination and/or the in-band scattered illumination as compared to the higher power of the in-band illumination.

The integrator 206 may be coupled to the output of the photodiode 204. The integrator 206 may receive current from the photodiode 204. The photodiode 204 may be biased through a current mirror 216 that is supplied from the bias voltage source 218. The mirrored current may be converted to a voltage by resistor 220. The integrator 206 may integrate the current from the photodiode 204 to determine a dosage 207. Integration of the current output from the photodiode 204 may provide the dosage 207 of the photodiode 204. The dosage 207 may be in Joules per square centimeter (J/cm²). The dosage (J/cm²) relates to the irradiance (W/cm²) times the duration in seconds. The equations are:

$${I}_{diode} ( A ) = Irradience ( W / {cm}^{2} ) \cdot {ℛ}_{( λ )} ( A / W ) \cdot Area ( {cm}^{2} ) \qquad ( 1 )$$

$${V}_{D o s a g e} ( V ) = \frac{{I}_{d i o d e} \cdot t ( Sec )}{C ( F )} \qquad ( 2 )$$

By substitution of (1), and that 1 W·second=1J

$$Dosage ( J / {cm}^{2} ) = \frac{{V}_{Dosage} \cdot C ( F )}{ℛ ( A / W ) \cdot Area ( {cm}^{2} )} \qquad ( 3 )$$

Setting a constant, k, to Area/C in unit of cm²/F equation 3, reduces to:

$$Dosage ( J / {cm}^{2} ) = \frac{{V}_{Dosage}}{k ( {cm}^{2} / F )} \qquad ( 4 )$$

Where I_{diode}(A) is the current through the photodiode in amps, Irradience(W/cm²) is the irradiance of the illumination 101 in watts per square (centimeter, R_{(λ)} is the responsivity at a given wavelength in Amps per watt, the Area is the area of the photodiode 204 in square centimeters, the t(Sec) is the time in seconds over which the current is integrated by the integrator 206, the C(F) is the capacitance in Farads of the integrator 206 (e.g., of a capacitor within the integrator 206), and Dosage (J/cm²) is the dosage 207 in joules per square centimeter of the illumination 101 received by the photodiode 204.

The in-band dosage sensors 116 and/or the in-band scattered dosage sensors 120 may include the responsivity which is in-band with the EUV illumination (e.g., at 10 to 20 nanometers). The responsivity of the in-band scattered dosage sensors 120 may be much higher than the responsivity of the in-band dosage sensors 116 to accommodate for the lower percentage of the in-band scattered illumination as compared to the higher percentage of the in-band EUV illumination which is in the scan area. For example, the photodiode 204 of the in-band dosage sensors 116 may include a responsivity, R, of 0.25 A/W for the illumination 101 at 13.5 nanometers.

The dosage 207 may be the power of the illumination 101 divided by the area of the illumination 101 times the time at which the illumination 101 exposes the in-band dosage sensors 116, the out-of-band dosage sensors 118, and/or the in-band scattered dosage sensors 120. For instance, the dosage 207 may also be the irradiance in watts per square centimeter (W/cm²) times a field size of the illumination 101 in centimeters divided by a scan speed of the illumination 101 in centimeters per second (cm/s).

The voltage may be integrated over period, wherein the period includes a sequence of pulses that forms a scan. The integration over the period may determine the total energy of the scan of the illumination 101. The integrator 206 may integrate the total energy under “burst” of light pulses to the total energy, measured in mJ.

The controller 104 may be coupled to the integrator 206. The controller 104 may be configured to activate and/or deactivate the integrator 206.

The analog-to-digital converter 208 may be coupled to the output of the integrator 206. The analog-to-digital converter 208 may receive the dosage 207 from the integrator 206. The analog-to-digital converter 208 may convert the dosage 207 from the integrator 206 to the dosage measurements (e.g., the in-band dosage measurements 117, the out-of-band dosage measurements 119, and/or the in-band scattered dosage measurements 121). The analog-to-digital converter 208 may output the dosage measurements to the controller 104. The analog-to-digital converter 208 may generate the dosage measurements from the dosage 207 upon the integrator 206 being deactivated.

The dosage measurements (e.g., the in-band dosage measurements 117, the out-of-band dosage measurements 119, and/or the in-band scattered dosage measurements 121) may be a slit-integrated energy (SLIE). The slit-integrated energy may be the in-band EUV energy per-pulse per-unit distance. The unit distance may be along an x-axis where the x-axis is in-plane to the instrumented substrate 100. The slit-integrated energy may include units of J/m.

The comparator 210 may be coupled to the output of the current mirror 216. The comparator 210 may receive voltage from the resistor 220. comparator 210. The comparator 210 may detect the pulses of the illumination 101. The comparator 210 may detect the pulses of the illumination 101 as a means of detecting the beginning and the end of the pulses of the illumination 101. The comparator 210 may output 211 the detection of the pulses of the illumination 101 to the controller 104. The comparator 210 may be connected to a pulse counter within the controller 104. The pulse counter may count the number of pulses detected.

The controller 104 may determine a time in which the in-band dosage sensors 116, the out-of-band dosage sensors 118, and/or the in-band scattered dosage sensors 120 receive the illumination 101 from the pulses detected by the comparator 210. The time in which the in-band dosage sensors 116, the out-of-band dosage sensors 118, and/or the in-band scattered dosage sensors 120 receive the illumination 101 may also be referred to as radiation temporal bursts. The controller 104 may execute an adaptive learning algorithm using the pulses detected by the comparator 210. The adaptive learning algorithm may predict and gate the measurement of future pulses of the illumination 101. The controller 104 may predict a repeating pattern of pulses of the illumination 101 for determining the period in which to activate and deactivate the integrator 206.

The controller 104 may activate and deactivate the integrator 206 based on the pulses detected by the comparator 210. The controller 104 may activate and deactivate the integrator 206 via a signal line 205. The controller 104 may activate the integrator 206 for the period. The controller 104 may be configured to activate the integrator 206 before the illumination 101 pulses on the in-band dosage sensors 116, the out-of-band dosage sensors 118, and/or the in-band scattered dosage sensors 120. The controller 104 may keep the integrator 206 active for the duration in which the in-band dosage sensors 116, the out-of-band dosage sensors 118, and/or the in-band scattered dosage sensors 120 receives the illumination 101. The duration in which the in-band dosage sensors 116, the out-of-band dosage sensors 118, and/or the in-band scattered dosage sensors 120 receives the illumination 101 may be equal to the scan speed of the illumination 101 divided by the sum of a field size of the illumination 101 and a diameter of the aperture 214. The controller 104 may deactivate the integrator 206 after the in-band dosage sensors 116, the out-of-band dosage sensors 118, and/or the in-band scattered dosage sensors 120 stop receiving the illumination 101. Thus, the controller 104 may activate the integrator 206 for the period in which the in-band dosage sensors 116, the out-of-band dosage sensors 118, and/or the in-band scattered dosage sensors 120 receive the illumination 101 with tolerances before the illumination 101 is received and with tolerances after the illumination 101 is no longer received. Activating and deactivating the integrator 206 based on the pulses detected by the comparator 210 may ensure the entire dosage of the illumination 101 is measured, maximize the available storage in the memory 107, and/or avoid storing irrelevant data in the memory 107.

For example, FIG. 2C depicts a graph of the dosage 207 determined by the integrator 206 from five sequential scans of the illumination 101. In the first scan of the illumination 101, the controller 104 has activated the integrator 206 after the first scan is initially received, as indicated by comparator 210, such that the entire portion of the dosage of the first scan of the illumination 101 may not have been captured during integration. The duration of the scan in the dosage 207 may be determined when the pulses from comparator 210 ceases. Assuming that burst are sufficiently similar in repetition rate and burst length, the controller 104 may predict a future start time for the third scan after the determination of the start of the second scan detected the same way as the first scan. In the third through fifth scans, the controller 104 has activated the integrator 206 before the scans are initially received, predicted by the repetition-rate and pulse duration interval such that the entire portion of the dosage of the scans of the illumination 101 are captured during integration. The controller 104 deactivates the integrator 206 after the pulses are no longer detected by the comparator 210 and then receives the dosage measurements which are correct for the third through fifth scans from the analog-to-digital converter 208.

The controller 104 may determine a scanning pattern of the illumination 101 across the instrumented substrate 100 from the pulses of the illumination 101 detected by the comparator 210 from multiple of the in-band dosage sensors 116, the out-of-band dosage sensors 118, and/or the in-band scattered dosage sensors 120. The scanning pattern may refer to a pattern in which the illumination 101 follows along the substrate 102. The scanning pattern may include a pattern and/or a time in which the in-band dosage sensors 116, the out-of-band dosage sensors 118, and/or the in-band scattered dosage sensors 120 receive the illumination 101. The controller 104 may synchronize generating the in-band dosage measurements 117, the out-of-band dosage measurements 119, and/or the in-band scattered dosage measurements 121 to the scanning pattern.

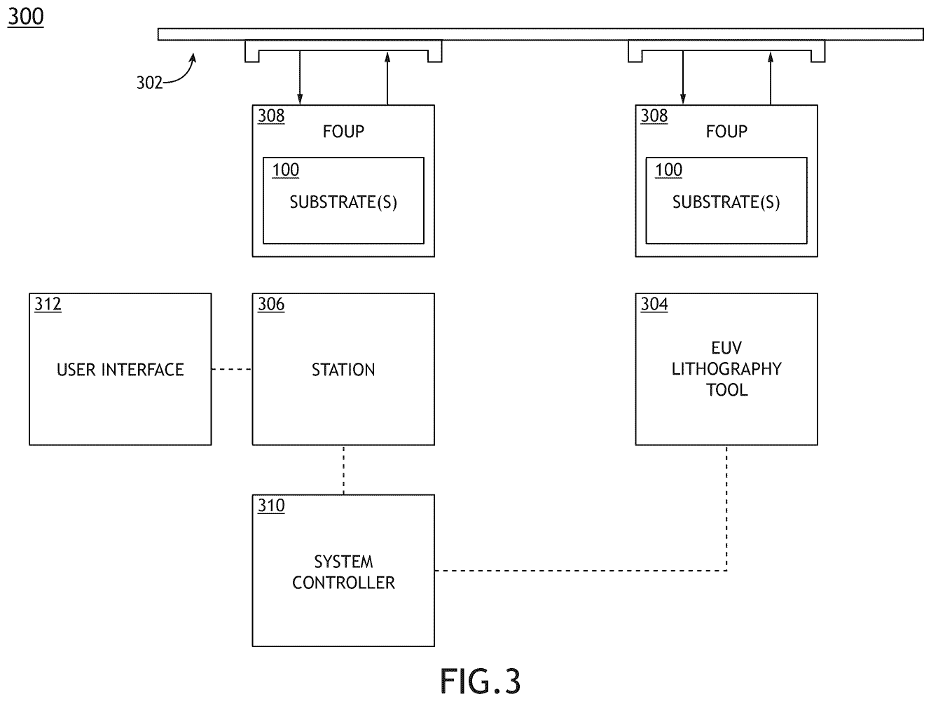

FIG. 3 illustrates a simplified block diagram of a system 300, in accordance with one or more embodiments of the present disclosure. The system 300 may be a substrate processing system. The system 300 may include the instrumented substrate 100, an automatic material handling system 302 (AMHS), an EUV lithography tool 304, a station 306, front opening unified pods 308 (FOUP), a system controller 310, and/or a user interface 312.

The front opening unified pods 308 may be automation ready FOUPs. The front opening unified pods 308 may include one or more of the instrumented substrates 100. The front opening unified pods 308 may be configured to receive and secure the instrumented substrates 100. The instrumented substrate 100 may be housed within the front opening unified pods 308. The front opening unified pods 308 may include a substrate carrier which may be integrated with the system 300. The front opening unified pods 308 may provide an environment for storing and transporting the instrumented substrate 100.

The front opening unified pods 308 may be configured to provide power to the power source 108. For example, the front opening unified pods 308 may recharge the power source 108.

The front opening unified pods 308 may be configured to exchange data with the communication interface 110. For example, the front opening unified pods 308 may be configured to receive the sensor measurements 115, the in-band dosage measurements 117, the out-of-band dosage measurements 119, the signal composition, and/or in-band scattered dosage measurements 121 from the communication interface 110. The controller 104 of the instrumented substrate 100 may be communicatively coupled to the front opening unified pods 308 by wireless communication. For instance, the front opening unified pods 308 may include communication circuitry (not depicted). The communication circuitry may include, but is not limited to, one or more communication antennas (e.g., communication coil). In embodiments, the communication circuitry is configured to establish a communication link between the controller 104 and the front opening unified pods 308. The front opening unified pods 308 may include a FOUP interface (not depicted). The FOUP interface may be the interface by which the front opening unified pods 308 may be configured to receive recipes, mission start command, relays back mission data, and the like.

The automatic material handling system 302 may position the front opening unified pods 308 in three-dimensions. The automatic material handling system 302 may include an Overhead track (OHT) system. The space occupied by the automatic material handling system 302 may be above the normal floor working level. The automatic material handling system 302 may pick the front opening unified pods 308 from the station 306 and transport the front opening unified pods 308 to the EUV lithography tool 304. Similarly, the automatic material handling system 302 may pick the front opening unified pods 308 from the EUV lithography tool 304 and transport the front opening unified pods 308 to the station 306.

The station 306 may be an automation station. The station 306 may be an Automated material handling system (AMHS) compatible station. The station 306 may host the front opening unified pods 308. The station 306 may be configured to receive the front opening unified pods 308. The station 306 may communicate with the front opening unified pods 308. The station 306 may also recharge the front opening unified pods 308. The station 306 may communicate with the system controller 310.

The EUV lithography tool 304 may be configured to receive the instrumented substrate 100. The automatic material handling system 302 may also be configured to remove the instrumented substrate 100 from the front opening unified pods 308 and place the instrumented substrate 100 within a pathway of the illumination 101.

The EUV lithography tool 304 may be configured to generate the illumination 101. The EUV lithography tool 304 may be configured to generate the illumination 101 using a plasma or the like. For example, the EUV lithography tool 304 may include an EUV lithography tool produced by ASML™, or the like. The EUV lithography tool 304 may generate the illumination 101 in an image plane on the instrumented substrate 100.

The instrumented substrate 100 may provide a metrology platform for calibrating and monitoring the illumination 101 in the EUV lithography tool 304. The EUV lithography tool 304 may use the signal composition of the illumination 101 determined by the controller 104, the sensor measurements 115, the in-band dosage measurements 117, the out-of-band dosage measurements 119, and/or the in-band scattered dosage measurements 121 for optimal semiconductor process performance. The instrumented substrate 100 may enable tool matching to within 1% dosage. The EUV lithography tool 304 may be unable to provide stability better than a few percent. However, exposure levels of the EUV lithography tool 304 must be measured and controlled to within 0.5%. The instrumented substrate 100 may enabling measuring and controlling the exposure levels of the EUV lithography tool 304 to within 0.5%. The instrumented substrate 100 may provide system-to-system exposure control or transfer. The EUV lithography tool 304 may use the EUV radiation, the out-of-band, and/or the diffuse in-band radiation may be used for chamber matching, statistical process control (SPC) monitoring, recipe development, and debugging.

The instrumented substrate 100 may be configured to autonomously perform a measurement of the illumination 101 in response to a factory automation request.

The system controller 310 and the instrumented substrate 100 may include an interface through the front opening unified pods 308 and the station 306 and/or an interface through the EUV lithography tool 304. The system controller 310 may process data from the instrumented substrate 100 for statistical processing control (SPC). The system 300 may have the ability to automatically add data collected from the instrumented substrate 100 to a database within the system controller 310.

A mission may be a data collection session of the instrumented substrate 100 and the following download of data from the instrumented substrate 100. The mission may be initiated by the system controller 310 for the purpose to ascertain the health of the EUV lithography tool 304. The mission may be communicated to the station 306 that hosts the front opening unified pods 308. The station 306 may communicate the mission to the front opening unified pods 308. The front opening unified pods 308 may then communicate the mission to the instrumented substrate 100. The instrumented substrate 100 may then execute the mission for determining the health of the EUV lithography tool 304.

The user interface 312 may be communicatively coupled to the station 306. The user interface 312 may include, but is not limited to, one or more desktops, laptops, tablets, and the like. The user interface 312 may include a display used to display data of the system to a user. The display of the user interface 312 may include any display known in the art. For example, the display may include, but is not limited to, a liquid crystal display (LCD), an organic light-emitting diode (OLED) based display, or a CRT display. Those skilled in the art should recognize that any display device capable of integration with a user interface is suitable for implementation in the present disclosure. A user may input selections and/or instructions responsive to data displayed to the user via a user input device of the user interface 312.

Any of the various components of the system 300 may be configured to communicate using a selected communications protocol. For example, the selected communications protocol may include an industry standard communications protocol consistent with standards defined by the Semiconductor Equipment and Materials Institute (SEMI). These standards are referred to as SEMI Equipment Communications Standards (SECS) and Generic Equipment Model (GEM).

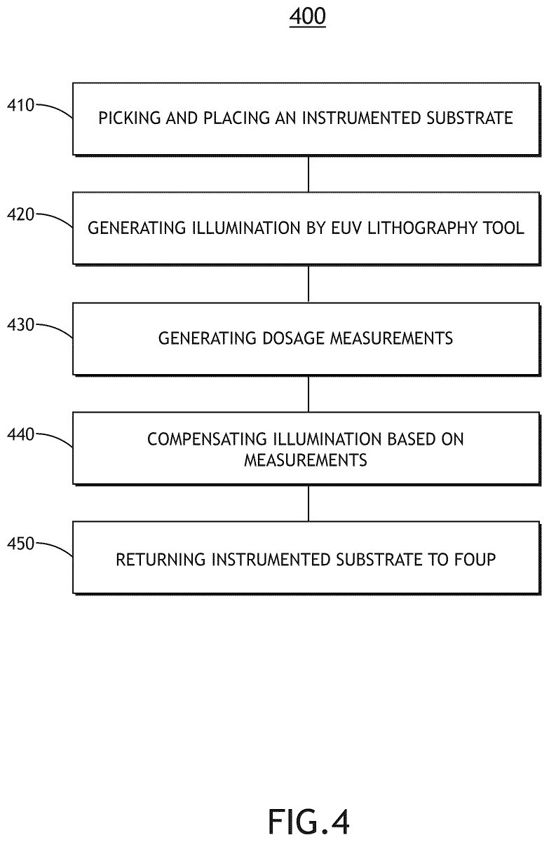

Referring now to FIG. 4, a method 400 is described, in accordance with one or more embodiments of the present disclosure. The method may be for measuring the illumination 101. The embodiments and the enabling technologies described previously herein in the context of the instrumented substrate 100 and system 300 should be interpreted to extend to the method. It is further noted, however, that the method is not limited to the architecture of the instrumented substrate 100 and the system 300.

In a step 410, an instrumented substrate may be picked and placed from a front opening unified pod onto a EUV lithography tool. For example, the instrumented substrate 100 may be picked and placed from the front opening unified pod 408 onto the EUV lithography tool 304.

In a step 420, the EUV lithography tool may generate illumination. For example, the EUV lithography tool 304 may generate the illumination 101. The EUV lithography tool 304 may require calibration of the illumination 101.

In a step 430, the instrumented substrate may generate dosage measurements from the illumination. For example, the instrumented substrate 100 may generate in-band dosage measurements 117, out-of-band dosage measurements 119, and/or in-band scattered dosage measurements 121 from the illumination 101. The instrumented substrate 100 may generate the sensor measurements 115, the in-band dosage measurements 117, the out-of-band dosage measurements 119, and/or the in-band scattered dosage measurements 121 from the illumination 101 using the sensors 114, the in-band dosage sensors 116, the out-of-band dosage sensors 118, and the in-band scattered dosage sensors 120, respectively.

In a step 440, the EUV lithography tool may compensate the illumination based on the dosage measurements. For example, the EUV lithography tool 304 may compensate the illumination 101 based on the in-band dosage measurements 117, out-of-band dosage measurements 119, the signal composition of the illumination 101, and/or in-band scattered dosage measurements 121. The in-band dosage measurements 117, the out-of-band dosage measurements 119, the signal composition of the illumination 101, and/or the in-band scattered dosage measurements 121 may be sent from the instrumented substrate 100 to the EUV lithography tool 304 for compensating the illumination 101.

In a step 450, the instrumented substrate may be returned to the front opening unified pod. For example, the instrumented substrate 100 may be returned to the front opening unified pod 408.

In embodiments, each of the steps may be performed automatically by the system 300 so that the instrumented substrate 100 may be accurately positioned efficiently without requiring human intervention. In embodiments, the steps may be iteratively performed to increase the accuracy of the position.

Any of the various optical elements may be manufactured using any suitable process. For example, the various optical elements may be fabricated using 3D printing or the like. The optical components may be made using a fabrication process. For example, the optical components may be made by molding (e.g., injection molding, glass molding, blank molding), casting, embossing, and the like. The optical components may be made of a material. For example, the optical components may be made of a plastic, glass, or the like.

The one or more processors may include any processor or processing element known in the art. For the purposes of the present disclosure, the term “processor” or “processing element” may be broadly defined to encompass any device having one or more processing or logic elements (e.g., one or more micro-processor devices, one or more application specific integrated circuit (ASIC) devices, one or more field programmable gate arrays (FPGAs), or one or more digital signal processors (DSPs)). In this sense, the one or more processors may include any device configured to execute algorithms and/or instructions (e.g., program instructions stored in memory). In one embodiment, the one or more processors may be embodied as a desktop computer, mainframe computer system, workstation, image computer, parallel processor, networked computer, or any other computer system configured to execute a program. Moreover, different subsystems of the system may include a processor or logic elements suitable for carrying out at least a portion of the steps described in the present disclosure. Therefore, the above description should not be interpreted as a limitation on the embodiments of the present disclosure but merely as an illustration. Further, the steps described throughout the present disclosure may be carried out by a single controller or, alternatively, multiple controllers.

In embodiments, a controller may include one or more controllers housed in a common housing or within multiple housings. In this way, any controller or combination of controllers may be separately packaged as a module suitable for integration into a system. Further, the controllers may analyze data received from detectors and feed the data to additional components within the system or external to the system.

The memory medium may include any storage medium known in the art suitable for storing program instructions executable by the associated one or more processors. For example, the memory medium may include a non-transitory memory medium. By way of another example, the memory medium may include, but is not limited to, a read-only memory (ROM), a random-access memory (RAM), a magnetic or optical memory device (e.g., disk), a magnetic tape, a solid-state drive and the like. The memory medium may include flash memory cells, or other type memory, discrete EPROM or EEPROM, or the like. It is further noted that memory medium may be housed in a common controller housing with the one or more processors. In one embodiment, the memory medium may be located remotely with respect to the physical location of the one or more processors and controller. For instance, the one or more processors of controller may access a remote memory (e.g., server), accessible through a network (e.g., internet, intranet and the like).

As used throughout the present disclosure, the term “substrate” generally refers to a substrate formed of a semiconductor or non-semiconductor material (e.g., thin filmed glass, or the like). For example, a semiconductor or non-semiconductor material may include, but is not limited to, monocrystalline silicon, gallium arsenide, indium phosphide, or a glass material. A substrate may include one or more layers. For example, such layers may include, but are not limited to, a resist (including a photoresist), a dielectric material, a conductive material, and a semiconductive material. Many different types of such layers are known in the art, and the term sample as used herein is intended to encompass a substrate on which all types of such layers may be formed. One or more layers formed on a substrate may be patterned or un-patterned. For example, a substrate may include a plurality of dies, each having repeatable patterned features. Formation and processing of such layers of material may ultimately result in completed devices. Many different types of devices may be formed on a substrate, and the term substrate as used herein is intended to encompass a substrate on which any type of device known in the art is being fabricated. Further, for the purposes of the present disclosure, the term substrate and wafer should be interpreted as interchangeable. In addition, for the purposes of the present disclosure, the terms patterning device, mask and reticle should be interpreted as interchangeable.

It is further contemplated that each of the embodiments of the methods described above may include any other step(s) of any other method(s) described herein. In addition, each of the embodiments of the method described above may be performed by any of the systems described herein.

One skilled in the art will recognize that the herein described components operations, devices, objects, and the discussion accompanying them are used as examples for the sake of conceptual clarity and that various configuration modifications are contemplated. Consequently, as used herein, the specific exemplars set forth and the accompanying discussion are intended to be representative of their more general classes. In general, use of any specific exemplar is intended to be representative of its class, and the non-inclusion of specific components, operations, devices, and objects should not be taken as limiting.

As used herein, directional terms such as “top,” “bottom,” “over,” “under,” “upper,” “upward,” “lower,” “down,” and “downward” are intended to provide relative positions for purposes of description, and are not intended to designate an absolute frame of reference. Various modifications to the described embodiments will be apparent to those with skill in the art, and the general principles defined herein may be applied to other embodiments

With respect to the use of substantially any plural and/or singular terms herein, those having skill in the art can translate from the plural to the singular and/or from the singular to the plural as is appropriate to the context and/or application. The various singular/plural permutations are not expressly set forth herein for sake of clarity.

The herein described subject matter sometimes illustrates different components contained within, or connected with, other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “connected,” or “coupled,” to each other to achieve the desired functionality, and any two components capable of being so associated can also be viewed as being “couplable,” to each other to achieve the desired functionality. Specific examples of couplable include but are not limited to physically mixable and/or physically interacting components and/or wirelessly interactable and/or wirelessly interacting components and/or logically interacting and/or logically interactable components.

Furthermore, it is to be understood that the invention is defined by the appended claims. It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” and the like). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, and the like” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, and the like). In those instances where a convention analogous to “at least one of A, B, or C, and the like” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, and the like). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

It is believed that the present disclosure and many of its attendant advantages will be understood by the foregoing description, and it will be apparent that various changes may be made in the form, construction and arrangement of the components without departing from the disclosed subject matter or without sacrificing all of its material advantages. The form described is merely explanatory, and it is the intention of the following claims to encompass and include such changes. Furthermore, it is to be understood that the invention is defined by the appended claims.

What is claimed:

1. An instrumented substrate comprising:
a substrate, wherein the substrate is configured to receive illumination, wherein the illumination comprises in-band EUV illumination and out-of-band illumination;
a power source;
a communication interface;
a plurality of conductive traces;
one or more in-band dosage sensors, wherein the one or more in-band dosage sensors are configured to generate in-band dosage measurements from the in-band EUV illumination; and
a controller comprising:
a memory maintaining program instructions; and
one or more processors configured to execute the program instructions.

2. The instrumented substrate of claim 1, comprising one or more out-of-band dosage sensors, wherein the one or more out-of-band dosage sensors are configured to generate out-of-band dosage measurements from the out-of-band illumination.

3. The instrumented substrate of claim 2, wherein the controller is configured to compare the in-band dosage measurements with the out-of-band dosage measurements to determine a signal composition of the illumination.

4. The instrumented substrate of claim 3, wherein the in-band dosage measurements are divided by the out-of-band dosage measurements to determine the signal composition.

5. The instrumented substrate of claim 3, wherein the communication interface is configured to transmit at least one of the in-band dosage measurements, the out-of-band dosage measurements, or the signal composition of the illumination from the instrumented substrate.

6. The instrumented substrate of claim 2, wherein the one or more in-band dosage sensors are adjacent to the one or more out-of-band dosage sensors.

7. The instrumented substrate of claim 1, wherein the in-band EUV illumination is between 10 and 20 nanometers.

8. The instrumented substrate of claim 1, wherein the out-of-band illumination is between 100 and 400 nanometers.

9. The instrumented substrate of claim 1, comprising one or more in-band scattered dosage sensors, wherein the illumination comprises in-band scattered EUV illumination, wherein the one or more in-band scattered dosage sensors are configured to generate in-band scattered dosage measurements from the in-band scattered EUV illumination.

10. The instrumented substrate of claim 1, wherein the one or more in-band dosage sensors comprise:
an absorptive layer, wherein the absorptive layer defines a cavity and an aperture;
a photodiode, wherein the photodiode is disposed in the cavity and aligned with the aperture, wherein the photodiode is configured to receive the illumination through the aperture;
an integrator, wherein the integrator is configured to receive current from the photodiode and integrate the current to determine a dosage; and
an analog-to-digital converter, wherein the analog-to-digital converter is configured to convert the dosage to the in-band dosage measurements.

11. The instrumented substrate of claim 10, wherein the photodiode comprises a silicon photodiode or a silicon carbide photodiode.

12. The instrumented substrate of claim 10, wherein the illumination is generated in pulses, wherein the one or more in-band dosage sensors comprise a comparator, wherein the comparator is configured to detect the pulses of the illumination, wherein the controller is configured to activate and deactivate the integrator based on the pulses detected by the comparator.

13. The instrumented substrate of claim 12, comprising a plurality of in-band dosage sensors comprising the comparator, wherein the illumination is scanned across the substrate in a scanning pattern, wherein the controller is configured to determine the scanning pattern from the pulses of the illumination detected by the comparator of the plurality of in-band dosage sensors.

14. A system comprising:
an instrumented substrate comprising:
a substrate, wherein the substrate is configured to receive illumination, wherein the illumination comprises in-band EUV illumination and out-of-band illumination;
a power source;
a communication interface;
a plurality of conductive traces;
one or more in-band dosage sensors, wherein the one or more in-band dosage sensors are configured to generate in-band dosage measurements from the in-band EUV illumination; and
a controller comprising:
a memory maintaining program instructions; and
one or more processors configured to execute the program instructions; and
an EUV lithography system, wherein the EUV lithography system is configured to generate the illumination.

15. The system of claim 14, the instrumented substrate comprising one or more out-of-band dosage sensors, wherein the one or more out-of-band dosage sensors are configured to generate out-of-band dosage measurements from the out-of-band illumination.

16. The system of claim 15, wherein the controller is configured to compare the in-band dosage measurements with the out-of-band dosage measurements to determine a signal composition of the illumination.

17. The system of claim 16, wherein the communication interface is configured to transmit at least one of the in-band dosage measurements, the out-of-band dosage measurements, or the signal composition of the illumination from the instrumented substrate.

18. The system of claim 17, comprising a front opening unified pod; wherein the front opening unified pod is configured to receive the signal composition from the communication interface.

19. The system of claim 14, wherein the in-band EUV illumination is between 10 and 20 nanometers.

20. A method comprising:
picking and placing an instrumented substrate from a front opening unified pod onto a EUV lithography tool, wherein the instrumented substrate comprises:
a substrate, wherein the substrate is configured to receive illumination, wherein the illumination comprises in-band EUV illumination and out-of-band illumination;
a power source;
a communication interface;
a plurality of conductive traces;
one or more in-band dosage sensors, wherein the one or more in-band dosage sensors are configured to generate in-band dosage measurements from the in-band EUV illumination; and
a controller comprising:
a memory maintaining program instructions; and
one or more processors configured to execute the program instructions;
generating the illumination by the EUV lithography tool;
generating the in-band dosage measurements from the illumination; and
returning the instrumented substrate to the front opening unified pod.
